(19) United States
(12) Patent Application Publication
(10) Pub. No.: US 2016/0068447 A1
(43) Pub. Date: Mar. 10, 2016

(54) CERAMIC JOINED BODY, HEAT-RESISTANT COMPONENT AND METHOD FOR MANUFACTURING CERAMIC JOINED BODY

(71) Applicant: IBIDEN CO., LTD., Gifu (JP)

(72) Inventor: Mingxu HAN, IBI-GUN, GIFU (JP)

(21) Appl. No.: 14/783,644

(22) PCT Filed: Mar. 19, 2014
(86) PCT No.: PCT/JP2014/057481

§ 371 Date: Oct. 9, 2015

(30) Foreign Application Priority Data
Apr. 12, 2013 (JP) 2013-083425

(51) Int. Cl. C04B 37/00; C04B 35/56; C23C 16/48; C04B 35/58

(52) U.S. Cl. CPC C04B 37/005; C04B 35/58; C04B 35/5615; C23C 16/483

(57) ABSTRACT

A ceramic assembly is provided with a first ceramic component having a first surface, a second ceramic component having a second surface, and a joining section comprising a CVD ceramic which fills the region where the first surface and the second surface face each other.

### TECHNICAL FIELD

The present invention relates to a ceramic joined body, a heat-resistant component using the same, and a method for manufacturing a ceramic joined body.

### BACKGROUND ART

Since ceramics are excellent in oxidation resistance, creep resistance, heat-shock resistance, and thermal conductivity and have high hardness and high strength, they are widely used in various fields as heat-resistant components such as wafer boats to be used in thermal treatment of semiconductor wafers, components for a plasma etcher apparatus, and components for a semiconductor manufacturing apparatus, in addition to heat-resistant components of industrial furnaces.

In such heat-resistant components, a complex shape and/or a large size have sometimes been required. However, in general, the machinability of ceramics is low, making it difficult to manufacture a complex shape by integral processing. Also, the large-size heat-resistant components often cannot be manufactured due to constraints in manufacturing facility size. Usually, a heat-resistant component is configured by dividing a plurality of parts and respective parts are joined to form a final heat-resistant component.

Patent Document 1 describes a method for joining ceramic components in which a plurality of ceramic components to be joined are placed by bringing desired joining sites close to each other and a SiC fixing coating layer is formed on surfaces of a plurality of the ceramic components by chemical vapor deposition, as a joining method in which ceramic components can be easily joined, the resulting joined body has high strength durability even under a high-temperature environment, and the method can be applicable to a complex shape. Also, it is described that, according to the joining method, a complex-shape ceramic joined body having heat resistance, acid resistance, high strength, and high purity can be obtained more easily as compared with conventional joining methods.

### BACKGROUND ART DOCUMENT

### Patent Document

Patent Document 1: JP-A-2001-048667

### SUMMARY OF THE INVENTION

### Problems that the Invention is to Solve

However, since outer surfaces of ceramic components are only joined with an SiC fixing coating layer by chemical vapor deposition in the above-described method, the strength at the joined portion is remarkably poor as compared with the peripheral portions.

One of objects of the present invention is to provide a high-strength ceramic joined body obtained by joining a plurality of ceramic components.

Another one of objects of the present invention is to provide a heat-resistant component using a high-strength ceramic joined body obtained by joining a plurality of ceramic components.

Still another one of objects of the present invention is to provide a method for manufacturing a high-strength ceramic joined body obtained by joining a plurality of ceramic components.

### Means for Solving the Problems

The ceramic joined body of the invention for solving the above problem includes a first ceramic component having a first face, a second ceramic component having a second face, and a joining part including a CVD ceramic that fills a region where the first face and the second face are facing each other.

Moreover, the heat-resistant component for solving the problem uses the above-described ceramic joined body.

Furthermore, the method for manufacturing a ceramic joined body of the invention for solving the above problem, includes:

placing a first ceramic component having a first face and a second ceramic component having a second face so as to form a gap where the first face and the second face are facing each other and

forming a joining part including a CVD ceramic that joins the first ceramic component and the second ceramic component by a photo-CVD method in which a source gas is fed to the gap and light irradiation is performed to the first face or the second face through the gap.

### BRIEF DESCRIPTION OF THE DRAWINGS

FIG. 1 is a perspective view of a ceramic joined body of Embodiment 1.

FIG. 2(a) is an A-A′ cross-sectional view in the vicinity of a joining part of Embodiment 1. FIGS. 2(b) to 2(d) are cross-sectional views of modified examples of Embodiment 1.

FIG. 3(a) is a perspective view of a ceramic joined body of Embodiment 2. FIG. 3(b) is a perspective view of a ceramic joined body of Embodiment 3.

FIG. 4 is a cross-sectional view of a ceramic joined body of Embodiment 4 in which the first ceramic component and the second ceramic component each have a ceramic fiber.

FIG. 5 is a manufacturing apparatus for obtaining the ceramic joined body of Embodiment 1.

FIGS. 6(a) to 6(c) are explanatory views of a process for obtaining the ceramic joined body of Embodiment 1. FIG. 6(a) shows a process in which first and second ceramic components are placed, FIG. 6(c) shows a process in which the first and second ceramic components are joined with a joining part, and FIG. 6(b) shows an intermediate process thereof.

### MODES FOR CARRYING OUT THE INVENTION

The ceramic joined body, the heat-resistant component using the same, and the method for manufacturing a ceramic joined body according to the invention will be described in that order.

In the invention, the ceramic joined body is constituted by combining two components of the first ceramic component and the second ceramic component but may be constituted by combining three or more components.

In the invention, “integrally” is defined as two components that are adhered and joined without mechanical joining such as a screw and materials thereof may be different from each other.

### <<Ceramic Joined Body>>

The ceramic joined body of the invention comprises a first ceramic component having a first face, a second ceramic component having a second face, and a joining part including a CVD ceramic that fills a region where the first face and the second face are facing each other.

Namely, the ceramic joined body is obtained by joining the first ceramic component and the second ceramic component with the joining part. On this occasion, the first face of the first ceramic component and the second face of the second ceramic component are joined with the CVD ceramic.

Since the ceramic joined body of the invention can be integrally obtained by joining the first face and the second face, a large ceramic joined body can be easily obtained even when a manufacturing apparatus of the ceramic component is constrained in size.

The joining part of the ceramic joined body of the invention can be, for example, formed by placing the first face and the second face so as to form a gap where the first face and the second face are facing each other, feeding a source gas to the gap, and performing a photo-CVD method in which light irradiation is performed to the first face or the second face through the gap. Thus, the region where the first face and the second face are facing each other can be filled with the CVD ceramic. By the formation of the joining part, there is obtained a ceramic joined body where the first ceramic and second ceramic components are joined. The light irradiation to be used herein is not particularly limited. For example, lamp light sources such as low-pressure mercury lamp (wavelengths 184.9 nm and 253.7 nm), a high-pressure xenon lamp, and a deuterium lamp (150 to 300 nm) and also light sources such as a laser beam can be utilized. The laser beam can powerfully direct light irradiation energy focused on the gap where the first face and the second face are facing each other, so that the joining part can be efficiently formed.

The laser beam is not particularly limited and excimer lasers such as ArF (wavelength: 193 nm), KrF (wavelength: 248 nm), and XeF (wavelength: 351 nm), argon laser (417 nm, 514 nm), an He—Ne laser (632.8 nm), a CO₂ laser having a wavelength in a far-infrared region, a YAG laser having a wavelength in a near-infrared region (1064 nm), and harmonic waves thereof can be utilized. For example, when a fifth harmonic wave of the YAG laser is used, a light having a wavelength of 213 nm can be obtained. Moreover, the laser beam per unit area is desirably 10⁵ Wm⁻² or more and beam diameter is desirably from 1 μm to 100 mm. In order to increase an output, a plurality of laser beams may be combined and the laser beam can be simultaneously used in combination with plasma.

Thus, light irradiation is performed to the first face or the second face through the gap to grow the CVD ceramic from the first face or the second face by a photo-CVD method, and thereby the joining part can be formed.

The photo-CVD method is a method of exciting and thermally decomposing a source gas using high-energy (short wavelength) light irradiation to obtain a CVD ceramic. Therefore, the joining part is obtained without heating the first and second ceramic components that are base materials. The method has two advantages.

(1) Since it is not necessary to heat the first and second ceramic components that are base materials to a temperature at which the source gas is decomposed, a large CVD heating furnace is not needed. Therefore, a ceramic joined body having a joining part including a CVD ceramic can be easily obtained by using only an air-tight reaction vessel.

(2) since a joining part including a CVD ceramic can be obtained without heating the first and second ceramic components that are base materials and without raising temperature by exciting and thermally decomposing the source gas using high-energy (short wavelength) light irradiation, thermal strain is less likely to generate between the first and second ceramic components that are base materials and the joining part, so that a ceramic joined body having high strength can be obtained.

The source gas can be appropriately selected depending on the material of the joining part. Suitable source gas and CVD conditions necessary for obtaining the CVD ceramic of the joining part are known for each CVD ceramic and thus the CVD ceramic can be obtained using the gas and conditions by a known method.

The materials of the first and second ceramic components of the invention are not particularly limited as long as they are ceramics. For example, they may be alumina, zirconia, aluminum nitride, silicon carbide, silicon nitride, graphite, forsterite, steatite, cordierite, sialon, zircon, barium titanate, steatite, magnesia, ferrite, boron nitride, tungsten carbide, tantalum carbide, etc., oxide-based ceramics, carbide-based ceramics, nitride-based ceramics, and the like without particular limitation. Moreover, the materials of the first ceramic component and the second ceramic component may be the same or different. In the case where the materials of first ceramic component and the second ceramic component are the same, a large ceramic joined body with high strength which is joined with the joining part can be easily obtained. Moreover, in the case where the materials of first ceramic component and the second ceramic component are different, joining can be achieved with the joining part even when ceramics of a combination which cannot be usually integrally manufactured are combined and thus a ceramic joined body having high strength can be integrally obtained.

The first and second faces of the ceramic joined body of the invention may be a planar face or a curved face without particular limitation but are preferably a planar face. When they are planar, light irradiation can be evenly performed, so that the CVD ceramic can be evenly grown.

The first and second faces of the ceramic joined body of the invention may have the same shape and the same size and may be different in shape and size. The first and second faces are appropriately selected according to the shape of the objective ceramic joined body. For example, in the case where the first and second faces have the same shape and the same size, it is possible to make the joining part inconspicuous, so that a ceramic joined body having apparently no joining part can be easily obtained.

The material of CVD ceramic of the ceramic joined body of the invention is not particularly limited as long as the ceramic can be formed by a CVD method. In addition to pyrolytic graphite, SiC, TaN, TaC, TiN, TiC, and the like, MAX phase ceramics such as Ti₃SiC₂ can also be utilized. The MAX phase ceramics will be described later in detail.

In he ceramic joined body of the invention preferably has a third face extending so as to be away from the joining part on the first ceramic component and has a first coating part including a CVD ceramic that coats the third face in the vicinity of the joining part. The CVD ceramic of the first coating part can be formed simultaneously with the CVD ceramic of the joining part. Therefore, since the first ceramic component and the second ceramic component can be jointed not only with the joining part but also with the first coating part, a ceramic joined body having high strength can be obtained.

It is preferable that the ceramic joined body having the first coating part further has a fourth face extending so as to be away from the joining part on the second ceramic component and has a second coating part including a CVD ceramic that coats the fourth face in the vicinity of the joining part. The CVD ceramics of the first coating part and the second coating part can be formed simultaneously with the CVD ceramic of the joining part. Therefore, since the first ceramic component and the second ceramic component can be jointed not only with the joining part but also with the first coating part and the second coating part, a ceramic joined body having high strength can be obtained.

Moreover, the third face and the fourth face are preferably present on the same planar face across the joining part. When the third face and the fourth face are present on the same planar face across the joining part, the joining part and the outer surface of the neighboring ceramic joined body can be made almost planar, so that it is less likely that stress is focused on the joining part. Therefore, a ceramic joined body having high strength can be obtained.

The shape of the ceramic joined body of the invention will be exemplified and the third face and the fourth face will be described. Incidentally, the shape of the ceramic joined body of the invention is not limited thereto.

In the case where plate-shaped first ceramic component and plate-shaped second ceramic component second ceramic component having the same thickness are joined at respective side faces so as not to have a difference in level and thus a ceramic joined body is obtained, two main faces of the first ceramic component become each the third face and two main faces of the second ceramic component become each the fourth face.

In the case where cylindrical first ceramic component and cylindrical second ceramic component having the same thickness are joined at respective bottom faces so as not to have a difference in level and thus a ceramic joined body is obtained, the side face of the first ceramic component becomes the third face and the side face of the second ceramic component becomes the fourth face.

In the case where square pipe-shaped first ceramic component and square pipe-shaped second ceramic component having the same bottom shape are joined at respective bottom faces so as not to have a difference in level and thus a ceramic joined body is obtained, the inner side face and outer side face of the first ceramic component become the third face and the inner side face and outer side face of the second ceramic component become the fourth face.

In the ceramic joined body of the invention, the CVD ceramic filled into the joining part is desirably thicker than both of the first coating part and the second coating part.

The thickness of the CVD ceramic filled into the joining part is defined as a distance from the surface of the joining part to the deepest point filled by the CVD ceramic and is not a distance between the first face and the second face.

For example, in the case where plate-shaped first ceramic component and plate-shaped second ceramic component second ceramic component having the same thickness are joined at respective side faces so as not to have a difference in level, the thickness of the first coating part, the thickness of the second coating part, and the thickness of the CVD ceramic filled into the joining part are each lengths measured in the same direction.

In the ceramic joined body having the first coating part and the second coating part, the first ceramic component and the second ceramic component are joined by facing the first face and the second face. Since the region where the first face and the second face are facing each other is filled with a CVD ceramic, the first face and the second face can be strongly joined. Moreover, the first coating part and the second coating part have a function of reducing stress focused on an end of the joining part. Namely, it is sufficient that the coating parts coat a boundary part between the joining part and the first or second ceramic component so as not to form a notch at the boundary part. Moreover, when the CVD ceramic filled into the joining part is thinner than both of the first coating part and the second coating part, the joining part can have a concave shape and it becomes difficult to join the first face and the second face strongly.

It is preferable that the joining part of the ceramic joined body of the invention is thinner at the inside than at the surface. As an example of a joining part that is thinner at the inside than at the surface, a type having a cross-section of the joining part is V-shaped or U-shaped may be mentioned. Such a shape may be configured so that the inside becomes thinner from the surfaces of not only one side but also both sides. In the case where the shape is configured from the surfaces of both sides, the cross-section of the joining part becomes a shape constricted in the middle. It is preferred that the growth direction of the CVD ceramic is one direction in the case where the shape is configured so as to become thinner from the surface of one side and the growth direction of the CVD ceramic is two directions from a central part toward surfaces in the case where the shape is configured so as to become thinner from the surfaces of both sides.

Thus, by configuring the joining part so as to be thinner at the inside than at the surface, the joining part can be formed sequentially from the depths by a CVD method. Therefore, cavities (pores) can be less likely to form at the joining part including the CVD ceramic. Moreover, when the joining part is thinner at the inside than at the surface, in the case where the CVD ceramic is formed by the photo-CVD method, it becomes possible to reach the bottom of the gap easily with light irradiation.

It is preferred that the first ceramic component of the ceramic joined body of the invention is a composite material having a ceramic fiber inside and an end part of the ceramic fiber protrudes from the first face into the joining part.

When the first ceramic component is a composite material having a ceramic fiber inside, a ceramic joined body having high strength can be obtained. Moreover, when an end part of the ceramic fiber protrudes from the first face into the joining part, the component can be joined to the joining part strongly.

The first ceramic component in which an end part of the ceramic fiber protrudes from the first face into the joining part can be, for example, obtained as follows. It may be obtained by processing the first face so that a matrix thereof is selectively etched. Also, a fracture surface resulting from splitting the first ceramic component including a composite material having a ceramic fiber inside by notching may be used as the first face. Since the ceramic fiber is extracted on the fracture surface of the composite material, both a protrusion of ceramic fiber and a hole resulting from the extraction of the ceramic fiber are generated. Moreover, upon the formation of the composite material, the matrix is partly formed and a side face on which the ceramic fiber is exposed may be used as the first face.

In the ceramic joined body in which the first ceramic component is the composite material having the ceramic fiber inside and the end part of the ceramic fiber protrudes from the first face into the joining part, it is further preferred that the second ceramic component is a composite material having a ceramic fiber inside and an end part of the ceramic fiber protrudes from the second face into the joining part. In addition to the first ceramic component, when a composite material having a ceramic fiber inside is used as the second ceramic component and the end part of the ceramic fiber protrudes from the second face into the joining part, both sides of the joining part can be reinforced with the ceramic fiber, so that a ceramic joined body having high strength can be obtained.

The second ceramic component in which an end part of the ceramic fiber protrudes from the second face into the joining part can be, for example, obtained as follows. It may be obtained by processing the second face so that a matrix thereof is selectively etched. Also, a fracture surface resulting from splitting the second ceramic component including a composite material having a ceramic fiber inside by notching may be used as the second face. Since extraction of the ceramic fiber is caused on the fracture surface of the composite material, both a protruding ceramic fiber and a hole resulting from the extraction of the ceramic fiber are generated. Moreover, upon the formation of the composite material, the matrix is partly formed and a side face on which the ceramic fiber is exposed may be used as the second face.

As the ceramic fiber for the ceramic joined body of the invention, any type of ceramic fiber may be utilized. For example, carbon fibers, SiC fibers, and the like can be utilized and may be used for both of the first ceramic component and the second ceramic component.

The CVD ceramic of the ceramic joined body of the invention is preferably including a MAX phase ceramic defined by the following composition formula:

Mₙ₊₁AXₙ
(a) M is any element selected from the group consisting of Sc, Ti, V, Cr, Zr, Nb, Mo, Hf, and Ta;
(b) A is any element selected from the group consisting of Al, Si, P, S, Ga, Ge, As, Cd, In, Sn, Ti, and Pb;
(c) X is Cor N; and
(d) n is 0.5 or more and 3 or less (0.5≦n≦3).

The MAX phase ceramic is known to have a crystal structure in which crystal lattices of a carbide or nitride of “M” that is a transition metal are stacked with sandwiching atomic layers of “A”. Therefore, since dislocation and transfer are both possible in the atomic layer of “A”, the ceramic has a characteristic feature that plastic deformation is possible at ordinary temperature. Namely, the joining part can be constituted by a CVD ceramic that is easily deformed plastically.

Therefore, in the case of a ceramic combination where any of the first ceramic component, the second ceramic component, and the joining part is different in material or form, internal stress to be generated can be mitigated.

Incidentally, the case where the forms of the first or second ceramic component and the joining part are different from each other includes the case of a combination of a CVD ceramic and a sintered body although they have the same composition.

The MAX phase ceramic of the ceramic joined body of the invention is preferably Ti₃SiC₂. Ti₃SiC₂ has a crystal structure in which the crystal lattices of TiC are stacked with sandwiching the atomic layers of Si. Basically, it shows properties similar to those of TiC and is a material excellent in compressive strength from room temperature to a high temperature. However, the Si—Si bond has a metallic bond character and thus a temperature coefficient of resistivity exhibits positive conductivity like a metal and also, since translocation and transfer are both possible in the Si atom, it also has a property of undergoing plastic deformation at ordinary temperature. Moreover, Si, Ti, and C constituting Ti₃SiC₂ are elements relatively easy to utilize and are also not harmful, so that they can be suitably utilized. Furthermore, Ti₃SiC₂ has a melting point of 3000° C. or higher and can be stably used until 2300° C. in the air and until 1800° C. under vacuum or in an inert atmosphere. Ti₃SiC₂ has a fracture toughness of 11.2 MPa·m^{0.5}, a thermal shock resistance ΔT (1400° C.) a Vickers hardness of 4 GPa (SiC 26 GPa), and thus has characteristics that it is hard and yet easy to process.

### <<Heat-Resistant Component>>

The ceramic joined body of the invention can be suitably utilized as heat-resistant components. The heat-resistant components include furnace walls, internal members, and the like of industrial furnaces such as a hot press, a heat treatment furnace, and a semiconductor manufacturing apparatus. When the ceramic joined body of the invention is used for heat-resistant members of such industrial furnaces, the first and second ceramic components are jointed with the joining part and integrally configured and the body has high strength, so that it can be applied to a large-size heat-resistant member and can be suitably utilized.

The ceramic joined body of the invention can be suitably utilized as a heat-resistant component for a semiconductor manufacturing apparatus. In particular, Ti₃SiC₂ is especially preferred. Since Ti₃SiC₂ has heat resistance, it can be suitably utilized as a heat-resistant component for a semiconductor manufacturing apparatus and also, since it contains no harmful element for manufacturing semiconductors, it can be appropriately utilized.

### <<Method for Manufacturing Ceramic Joined Body>>

The method for manufacturing a ceramic joined body according to the invention includes:

placing a first ceramic component having a first face and a second ceramic component having a second face so as to form a gap where the first face and the second face are facing each other and

forming a joining part including a CVD ceramic that joins the first ceramic component and the second ceramic component by a photo-CVD method in which a source gas is fed to the gap and light irradiation is performed to the first face or the second face through the gap.

Namely, a ceramic joined body is obtained by joining a first ceramic component and a second ceramic component with a joining part. On this occasion, a first face of the first ceramic component and a second face of the second ceramic component are joined with the joining part including a CVD ceramic.

According to the method for manufacturing a ceramic joined body of the invention, since the ceramic joined body can be integrally obtained, it is possible to provide a manufacturing method capable of easily obtaining a large ceramic joined body even when a manufacturing apparatus of ceramic components is constrained in size.

The joining part of the method for manufacturing a ceramic joined body of the invention can be, for example, formed by placing the first face and the second face so as to form a gap where the first face and the second face are facing each other, feeding a source gas to the gap, and performing a photo-CVD method in which light irradiation is performed to the first face or the second face passing through the gap. Thus, the region where the first face and the second face are facing each other can be filled with the CVD ceramic. A ceramic joined body can be obtained by joining the first ceramic component and the second ceramic component as above. The light irradiation to be used herein is not particularly limited. For example, lamp light sources such as low-pressure mercury lamp (wavelengths 184.9 nm and 253.7 nm), a high-pressure xenon lamp, and a deuterium lamp (150 to 300 nm) and also light sources such as a laser beam can be utilized. The laser beam can be powerfully directed and light irradiation energy can be focused on the gap where the first face and the second face are facing each other, so that the joining part can be efficiently formed.

The laser beam is not particularly limited and excimer lasers such as ArF (wavelength: 193 nm), KrF (wavelength: 248 nm), and XeF (wavelength: 351 nm), argon laser (417 nm, 514 nm), an He—Ne laser (632.8 nm), a CO₂ laser having a wavelength in a far-infrared region, a YAG laser having a wavelength in a near-infrared region (1064 nm), and harmonic waves thereof can be utilized. For example, when a fifth harmonic wave of the YAG laser is used, a light having a wavelength of 213 nm can be obtained.

Thus, light irradiation is performed to the first face or the second face through the gap to grow a CVD ceramic from the first face or the second face by a photo-CVD method, and thereby the joining part can be formed.

The photo-CVD method is a method of exciting and thermally decomposing a source gas using high-energy (short wavelength) light irradiation to obtain a CVD ceramic. Therefore, the joining part is obtained without heating the first and second ceramic components that are base materials. The method has two advantages.

(1) Since it is not necessary to heat the first and second ceramic components that are base materials to a temperature at which the source gas is decomposed, a large CVD heating furnace is not needed. Therefore, a ceramic joined body having a joining part including a CVD ceramic can be easily obtained by using a reaction vessel which can only hold air-tightness.

(2) since a joining part including a CVD ceramic can be obtained without heating the first and second ceramic components that are base materials and without raising temperature by exciting and thermally decomposing the source gas using high-energy (short wavelength) light irradiation, thermal strain is less likely to generate between the first and second ceramic components that are base materials and the joining part, so that a ceramic joined body having high strength can be easily obtained.

The source gas can be appropriately selected depending on the material of the joining part. Suitable source gas and CVD conditions necessary for obtaining the CVD ceramic of the joining part are known for each CVD ceramic and thus the CVD ceramic can be obtained using the gas and conditions by a known method.

For example, in the case where silicon carbide is grown by a photo-CVD method, a CVD ceramic can be obtained by using MTS (methyl-trichloro-silane) as a source gas, using hydrogen as a carrier gas, and using a CO2 laser (250 W, output density per unit area: 10⁵ Wm⁻² or more, beam diameter: 10 to 100 μm) as a light source.

The materials of the first and second ceramic components of the method for manufacturing a ceramic joined body of the invention are not particularly limited as long as they are ceramics. For example, they may be alumina, zirconia, aluminum nitride, silicon carbide, silicon nitride, graphite, forsterite, steatite, cordierite, sialon, zircon, barium titanate, steatite, magnesia, ferrite, boron nitride, tungsten carbide, tantalum carbide, etc., oxide-based ceramics, carbide-based ceramics, nitride-based ceramics, and the like without particular limitation. Moreover, the materials of the first ceramic component and the second ceramic component may be the same or different. In the case where the materials of first ceramic component and the second ceramic component are the same, a large ceramic joined body having high strength, which is joined with the joining part, can be easily obtained. Moreover, in the case where the materials of first ceramic component and the second ceramic component are different, joining can be achieved with the joining part even when ceramics of a combination which cannot be usually integrally manufactured are combined and thus a ceramic joined body having high strength can be integrally obtained.

The first and second faces of the method for manufacturing a ceramic joined body of the invention may be a planar face or a curved face without particular limitation but are preferably a planar face. When they are planar, light irradiation can be evenly performed, so that the CVD ceramic can be evenly grown.

The first and second faces of the method for manufacturing a ceramic joined body of the invention may have the same shape and the same size and may be different in shape and size. The first and second faces are appropriately selected according to the shape of the objective ceramic joined body. For example, in the case where the first and second faces have the same shape and the same size, it is possible to make the joining part inconspicuous, so that a ceramic joined body having apparently no joining part can be easily obtained.

The material of CVD ceramic of the method for manufacturing a ceramic joined body of the invention is not particularly limited as long as the ceramic can be formed by a CVD method. In addition to pyrolytic graphite, SiC, TaN, TaC, TiN, TiC, and the like, MAX phase ceramics such as Ti₃SiC₂ can also be utilized. The MAX phase ceramics will be described later in detail.

In the method for manufacturing a ceramic joined body of the invention, it is preferred that the first ceramic component has a third face extending so as to be away from the joining part and a first coating part including a CVD ceramic that coats the third face in the vicinity of the joining part is formed by performing the light irradiation so that the irradiation spreads out of the gap (irradiated into and around the gap).

The CVD ceramic of the first coating part can be formed simultaneously with the CVD ceramic of the joining part. Therefore, since the first ceramic component and the second ceramic component can be jointed not only with the joining part but also with the first coating part, a method for manufacturing a ceramic joined body having high strength can be provided.

In the method for manufacturing the ceramic joined body having the first coating part, it is preferred that the second ceramic component has a fourth face extending so as to be away from the joining part and a second coating part including a CVD ceramic that coats the fourth face in the vicinity of the joining part is formed by performing the light irradiation so that the irradiation spreads out of the gap.

The CVD ceramics of the first coating part and the second coating part can be formed simultaneously with the CVD ceramic of the joining part. Therefore, since the first ceramic component and the second ceramic component can be jointed not only with the joining part but also with the first coating part and the second coating part, a method for manufacturing a ceramic joined body having high strength can be provided.

Moreover, the third face and the fourth face are preferably present on the same planar face across the joining part. When the third face and the fourth face are preferably present on the same planar face across the joining part, the joining part and the outer surface of the neighboring ceramic joined body can be made almost planar, so that stress is less likely to be focused on the joining part. Therefore, a method for manufacturing a ceramic joined body having high strength can be provided.

The shape of the ceramic joined body of the invention will be exemplified below and the third face and the fourth face will be described. Incidentally, the shape of the ceramic joined body to be applied to the method for manufacturing a ceramic joined body of the invention is not limited thereto.

In the case where plate-shaped first ceramic component and plate-shaped second ceramic component second ceramic component having the same thickness are joined at respective side faces so as not to have a difference in level and thus a ceramic joined body is obtained, two main faces of the first ceramic component become each the third face and two main faces of the second ceramic component become each the fourth face.

In the case where cylindrical first ceramic component and cylindrical second ceramic component having the same thickness are joined at respective bottom faces so as not to have a difference in level and thus a ceramic joined body is obtained, the side face of the first ceramic component becomes the third face and the side face of the second ceramic component becomes the fourth face.

In the case where square pipe-shaped first ceramic component and square pipe-shaped second ceramic component having the same bottom shape are joined at respective bottom faces so as not to have a difference in level and thus a ceramic joined body is obtained, the inner side face and outer side face of the first ceramic component become each the third face and the inner side face and outer side face of the second ceramic component become each the fourth face.

In the method for manufacturing a ceramic joined body of the invention, the CVD ceramic filled into the joining part is preferably formed thicker than both of the first coating part and the second coating part by concentrating the light irradiation to the gap.

By performing the light irradiation centrally to the gap, energy for exciting and decomposing a source gas, such as a lamp light or a laser beam can be concentrated on the gap to grow the CVD ceramic selectively at the gap. A method for performing the light irradiation centrally to the gap is not particularly limited but a laser beam may be scanned so that the gap is irradiated selectively or a lamp light once diffused may be collected by an optical lens.

Incidentally, the thickness of the CVD ceramic filled into the joining part is defined as a distance from the surface of the joining part to the deepest point filled in the CVD ceramic and is not a distance between the first face and the second face.

For example, in the case where plate-shaped first ceramic component and plate-shaped second ceramic component second ceramic component having the same thickness are joined at respective side faces so as not to have a difference in level, the thickness of the first coating part, the thickness of the second coating part, and the thickness of the CVD ceramic filled into the joining part are each length measured in the same direction.

In the ceramic joined body having the first coating part and the second coating part, the first ceramic component and the second ceramic component have been joined, the first face and the second face facing each other. Since the region where the first face and the second face are facing each other is filled with a CVD ceramic, the first face and the second face can be strongly joined. Moreover, the first coating part and the second coating part have a function of reducing stress focused on an end of the joining part. Namely, it is sufficient that the coating parts coat a boundary part between the joining part and the first or second ceramic component so as not to form a notch at the boundary part. Moreover, when the CVD ceramic filled into the joining part is thinner than both of the first coating part and the second coating part, the joining part has a concave shape and it becomes difficult to join the first face and the second face strongly.

In the method for manufacturing a ceramic joined body of the invention, it is preferred that the joining part is configured so as to be thinner at the inside than at the surface by placing the first ceramic component and the second ceramic component so that the gap is thinner at the inside than at the surface. As an example of a joining part that is thinner at the inside than at the surface, a type where the cross-section of the joining part is V-shaped or U-shaped may be mentioned. As the cross-section of the gap corresponding to the above one, V-shaped one, U-shaped one, or the like may be mentioned. Such a shape may be configured so that the inside becomes thinner from the surfaces of not only one side but also both sides. In the case where the shape is configured so as to become thinner from both sides, the cross-section of the joining part becomes a shape constricted in the middle. It is preferred that the growth direction of the CVD ceramic is one direction in the case where the shape is configured so as to become thinner from the surface of one side and the CVD ceramic is grown from two directions, i.e., from a central part toward surfaces in the case where the shape is formed so as to become thinner from the surfaces of both sides.

Thus, by forming the joining part so as to be thinner at the inside than at the surface, the joining part can be formed sequentially from the depths by a CVD method. Therefore, cavities (pores) are less likely to form at the joining part including the CVD ceramic. Moreover, when the joining part is thinner at the inside than at the surface, in the case where the CVD ceramic is formed by the photo-CVD method, it becomes possible to reach the bottom of the gap easily with light irradiation.

In the method for manufacturing a ceramic joined body of the invention, it is preferred that the first ceramic component is a composite material having a ceramic fiber in which an end part of the ceramic fiber protrudes from the first face and the joining part is formed so that the end part is encapsulated.

When the first ceramic component is a composite material having a ceramic fiber inside, a ceramic joined body having high strength can be obtained. Moreover, when an end part of the ceramic fiber protrudes from the first face into the joining part, the component can be joined to the joining part strongly.

The first ceramic component in which an end part of the ceramic fiber protrudes from the first face into the joining part can be, for example, obtained as follows. It may be obtained by processing the first face so that a matrix thereof is selectively etched. Also, a fracture surface resulting from splitting the first ceramic component including a composite material having a ceramic fiber inside by notching may be used as the first face. Since extraction of the ceramic fiber is caused on the fracture surface of the composite material, both a protruding ceramic fiber and a hole resulting from the extraction of the ceramic fiber are generated. Moreover, upon the formation of the composite material, the matrix is partly formed and a side face on which the ceramic fiber is exposed may be used as the first face.

When the CVD ceramic is grown by the photo-CVD method on the first face from which an end part of the ceramic fiber protrudes as above, the joining part can be formed so that the end part is encapsulated.

In the method for manufacturing a ceramic joined body of the invention, it is preferred that the first ceramic component is a composite material having a ceramic fiber in which the end part of the ceramic fiber protrudes from the first face and the joining part is preferably formed so that the end part is encapsulated, and further, the second ceramic component is a composite material having a ceramic fiber in which an end part of the ceramic fiber protrudes from the second face and the joining part is formed so that the end part is encapsulated.

In addition to the first ceramic component, when a composite material having a ceramic fiber inside is used as the second ceramic component and the end part of the ceramic fiber protrudes from the second face into the joining part, both sides of the joining part can be reinforced with the ceramic fiber, so that a ceramic joined body having high strength can be obtained.

The second ceramic component in which an end part of the ceramic fiber protrudes from the second face into the joining part can be, for example, obtained as follows. It may be obtained by processing the second face so that a matrix thereof is selectively etched. Also, a fracture surface resulting from splitting the second ceramic component including a composite material having a ceramic fiber inside by notching may be used as the second face. Since extraction of the ceramic fiber is caused on the fracture surface of the composite material, both a protruding ceramic fiber and a hole resulting from the extraction of the ceramic fiber are generated. Moreover, upon the formation of the composite material, the matrix is partly formed and a side face on which the ceramic fiber is exposed may be used as the second face.

When the CVD ceramic is grown by the photo-CVD method on the first and second faces where an end part of the ceramic fiber protrudes into the joining part as above, the joining part can be formed simultaneously on both sides of the first and second faces so that the end part is encapsulated.

As the ceramic fiber to be used in the first ceramic component and the second ceramic component, any one can be utilized. For example, carbon fibers, SiC fibers, and the like can be utilized.

In the method for manufacturing a ceramic joined body of the invention, it is preferred that the CVD ceramic is including a MAX phase ceramic defined by the following composition formula:

Mn+1AXn

wherein the joining part is formed using

a halide, a hydride, or a hydrocarbylate containing M,

a halide, a hydride, or a hydrocarbylate containing A, and

an organic substance, an oxide, ammonia, or an amine containing X, as the source gas:

(a) M is any element selected from the group consisting of Sc, Ti, V, Cr, Zr, Nb, Mo, Hf, and Ta;

(b) A is any element selected from the group consisting of Al, Si, P, S, Ga, Ge, As, Cd, In, Sn, Ti, and Pb;

(c) X is C or N; and

(d) n is 0.5 or more and 3 or less (0.5≦n≦3).

The MAX phase ceramic is known to have a crystal structure in which crystal lattices of a carbide or nitride of “M” that is a transition metal are stacked with sandwiching atomic layers of “A”. Therefore, since dislocation and transfer are both possible in the atomic layer of “A”, the ceramic has a characteristic feature that plastic deformation is possible at ordinary temperature. Namely, the joining part can be constituted by a CVD ceramic that is easily deformed plastically.

Therefore, in the case of a ceramic combination where any of the first ceramic component, the second ceramic component, and the joining part is different in material or form, internal stress to be generated can be mitigated.

Incidentally, the case where the forms of the first or second ceramic component and the joining part are different includes the case of a combination of a CVD ceramic and a sintered body although they have the same composition.

Specifically, as the halide, hydride, or hydrocarbylate containing M, titanium halides (TiCl₄, TiF₄, TiBr₄, TiI₄, etc.), titanium hydrides (TiH₂) tantalum halides (TaC1₅), and the like may be mentioned. In the case where the halide, hydride, or hydrocarbylate containing M is solid or liquid, it may be used as a source gas by heating it to generate a gas.

Also, as the halide, hydride, or hydrocarbylate containing A, SiCl₄, SiF₄, SiBr₄, SiI₄, CH₃SiCl₃, C₂H₆SiC₁₂, C₃H₉SiCl, SiH4, and the like may be mentioned. In the case where the halide, hydride, or hydrocarbylate containing A is solid or liquid, it may be used as a source gas by heating it to generate a gas.

Furthermore, as the organic substance containing X, for example, hydrocarbon gases such as methane, ethane, propane, and ethylene, alcohols, and halogen-based hydrocarbons, and the like may be mentioned. As the oxide containing X, NOX, CO, CO₂, and the like may be mentioned. As the amine containing X, methylamine, dimethylamine, trimethylamine, and the like may be mentioned. In the case where the organic substance, oxide, or amine containing X is solid or liquid, it may be used as a source gas by heating it to generate a gas.

In order to obtain the CVD ceramic using the source gas, for example, it can be obtained by a photo-CVD method using reactions according to the following reaction formulae.

TiCl₄+CH₄+H₂-->TiC+4HCl (Formula 1)

SiCl₄+CH₄+H₂-->SiC+4HCl (Formula 2)

CH₃SiCl₃+H₂-->SiC+3HCl (Formula 3)

3TiCl₄+SiCl₄+2CH₄+H₂-->Ti₃SiC₂+16HCl (Formula 4)

2TaCl₅+2CH₄+H₂-->2TaC+10HCl (Formula 5)

They are appropriately combined and used as the source gas and hydrogen, argon, or the like may be used as a carrier gas. The carrier gas is mixed with the source gas and has a function of carrying the source gas and also a function of contributing to the reactions to control equilibrium reactions.

In these reactions, the source gas can be excited and decomposed by light irradiation to obtain the CVD ceramic.

In the method for manufacturing a ceramic joined body of the invention, it is preferred that the MAX phase ceramic is Ti₃SiC₂ and the joining part is formed using a titanium halide, a silicon halide, and a carbon halide as the source gas.

Ti₃SiC₂ has a crystal structure in which the crystal lattices of TiC are stacked with sandwiching the atomic layers of Si. Basically, it shows properties similar to those of TiC and is a material excellent in compressive strength from room temperature to a high temperature. However, the Si—Si bond has a metallic bond character and thus a temperature coefficient of resistivity exhibits positive conductivity like a metal and also, since translocation and transfer are both possible in the Si atom, it also has a property of undergoing plastic deformation at ordinary temperature. Moreover, Si, Ti, and C constituting Ti₃SiC₂ are elements relatively easy to utilize and are also not harmful, they can be suitably utilized. Furthermore, Ti₃SiC₂ has a melting point of 3000° C. or higher and can be stably used until 2300° C. in the air and until 1800° C. under vacuum or in an inert atmosphere. Ti3SiC2 has a fracture toughness of 11.2 MPa·m^{0.5}, a thermal shock resistance ΔT (1400° C.) a Vickers hardness of 4 GPa (26 GPa in case of SiC), and thus has characteristics that it is hard and yet easy to process.

In order to obtain a CVD ceramic using the source gas, for example, the reaction according to the reaction formula of Formula 3 can be utilized.

In the reaction, a jointing part can be formed using SiCl₄, CH₄, H₂ source gas, a carrier gas total pressure of 3.5 Torr, a temperature of 700° C., and a CO2 laser (output: 250 W, laser output per unit area: 10⁵Wm⁻² or more, beam diameter: 3 μm to 100 μm) as a laser beam.

Specific embodiments of the invention will be described below with reference to the accompanying drawings.

Embodiment 1 is a planar ceramic joined body, Embodiment 2 is a cylindrical ceramic joined body, and Embodiment 3 is a square pipe-shaped ceramic joined body. Embodiment 4 is a planar ceramic joined body but is different from Embodiment 1 in view that the first and second components are composite materials each having a ceramic fiber.

Therefore, in Embodiment 1, the shape of the ceramic joined body, the form of the joining part, and the manufacturing method will be described, while the shape will be mainly described in Embodiments 2 and 3. In Embodiment 4, the form of the joining part of the ceramic joined body and the manufacturing method will be mainly described.

### Embodiment 1

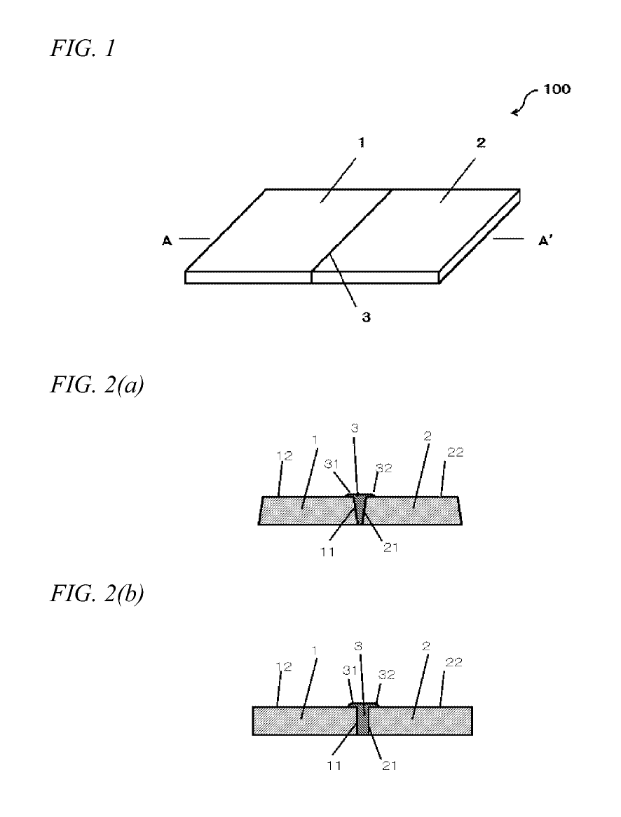

FIG. 1 shows a ceramic joined body of Embodiment 1 of the invention, in which the side faces of square flat plates having the same thickness are joined with a joining part.

FIG. 2(a) shows an A-A′ cross-sectional view in the vicinity of the joining part of the ceramic joined body of Embodiment 1 according to the invention. FIGS. 2(b) to 2(d) show modified examples of Embodiment 1 of the invention.

FIG. 5 is a manufacturing apparatus for obtaining the ceramic joined body of Embodiment 1 of the invention.

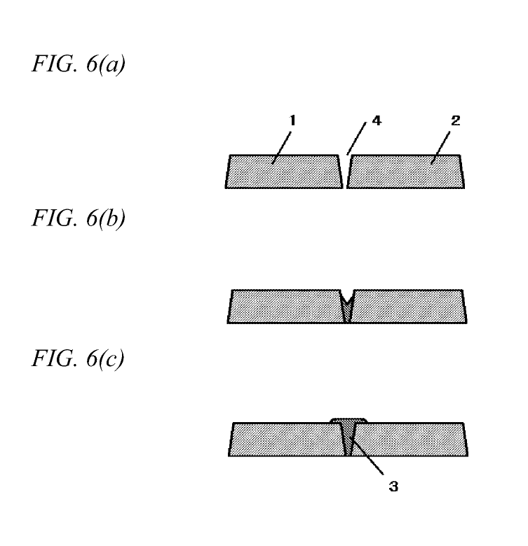

FIGS. 6(a) to 6(c) are explanatory views of a process for obtaining the ceramic joined body of Embodiment 1 of the invention. FIG. 6(a) shows a process in which first and second ceramic components are placed, FIG. 6(b) shows an intermediate process thereof, and FIG. 6(c) shows a process in which the first and second ceramic components are joined with a joining part.

A ceramic joined body 100 of Embodiment 1 of the invention is configured by combining a first ceramic component 1 and a second ceramic component 2 each having a thickness of 1 to 20 mm and having a rectangular shape in which one side is, for example, 100 to 500 mm as a size of the main face. The thickness of the first ceramic component 1 is the same as that of the second ceramic component 2. The first ceramic component 1 and the second ceramic component 2 use a sintered body of SiC.

The first face 11 of the first ceramic component 1 and the second face 21 of the second ceramic component 2 are each a face inclined by 80° to 87° toward the main face. The first ceramic component 1 and the second ceramic component 2 are placed in a reaction vessel so that a V-shaped gap 4 is formed in which a distance between the first face 11 of the first ceramic component 1 and the second face 21 of the second ceramic component 2 at the nearest part thereof is from 0.5 to 5 mm and the respective main faces of the first ceramic component 1 and the second ceramic component 2 become parallel. The source gas and the carrier gas are introduced from a gas inlet port 93 into the reaction vessel and excess source gas and carrier gas are discharged from a discharge port 94. Since the source gas and the carrier gas, partial pressure of which is controlled, are circulated, the partial pressure of the source gas and the carrier gas in the reaction vessel is controlled to a constant value. Through a window 92 of the reaction vessel, the formed V-shaped gap 4 is irradiated with a laser beam from a laser light source outside the reaction vessel. On this occasion, the laser beam is applied from the largely opened side of the V-shaped gap 4 so that the laser beam reaches a deep portion.

In the present embodiment, the reaction can be carried out under a reduced pressure of 400 Pa using MTS as a source gas and hydrogen as a carrier gas.

As the laser beam, a CO₂ laser (output: 250 W, laser output per unit area: 10⁶ Wm⁻², beam diameter: 20 μm) may be used. The laser beam is applied to the gap 4 as a narrow light beam. When the laser beam is scanned so that the beam is applied to the first face 11 and the second face 21, a CVD ceramic resulting from decomposition of the source gas is growing. The CVD ceramic obtained from the source gas, the conditions, and the like is silicon carbide.

When the grown joining part 3 reaches upper ends of the first ceramic component 1 and the second ceramic component 2, a first coating part 31 and a second coating part 32 can be formed by expanding the scanning range of the laser beam so that a third face 12 that is an upper main face of the first ceramic component 1 and a fourth face 22 that is an upper main face of the second ceramic component 2 are also irradiated. Since the thickness of the CVD ceramic can be controlled by the manner of scanning of the laser beam, the thickness of the first coating part 31 and the second coating part 32 can be controlled to, for example, 0.5 to 5 mm and the parts can be formed thinner than the joining part 3.

Since the thus obtained ceramic joined body 100 has high strength and large one is obtained, it may be used as a heat-resistant component for industrial furnaces and the like. Also, since the first ceramic component 1 and the second ceramic component 2 is used and the CVD ceramic contains no harmful element for the manufacture of semiconductors, the ceramic joined body may be used as a heat-resistant component for a semiconductor manufacturing apparatus.

FIG. 2(b) shows a modified example 1 of Embodiment 1, in which the distance between the first face 11 and the second face 12 is constant, regardless of the distance from surfaces. In this case, the joining part can be formed by providing a step of applying the laser beam obliquely to form the CVD ceramic preferentially on the bottom.

FIG. 2(c) shows a modified example 2 in which the thickness of the first ceramic component 1, the second ceramic component 2, and the joining part 3 is equal. In this case, the ceramic joined body can be obtained by stopping the irradiation with the laser beam at the stage that the joining part 3 reaches upper ends of the first ceramic component 1 and the second ceramic component 2. In this case, as the ceramic joined body 100, a flat surface with no difference in level can be obtained.

FIG. 2(d) shows a modified example 3 in which the joining part 3 is formed so that the inside becomes narrow from the surfaces of both sides of the ceramic joined body 100. In the case where it is configured so that the inside becomes narrow from the surfaces of both sides, the cross-section of the joining part 3 becomes a shape constricted in the middle. In this case, it can be obtained by applying the laser beam to the gap from both sides. The irradiation with the laser beam may be performed sequentially one side by one side or may be performed simultaneously from both sides. In the present modified example, since both sides are symmetrical, a ceramic joined body that is less likely to warp can be obtained.

### Embodiment 2

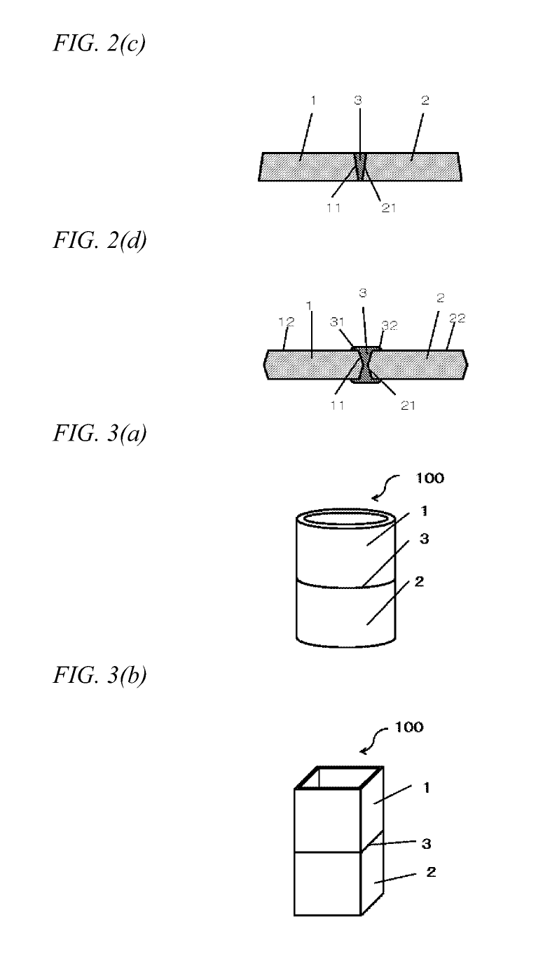

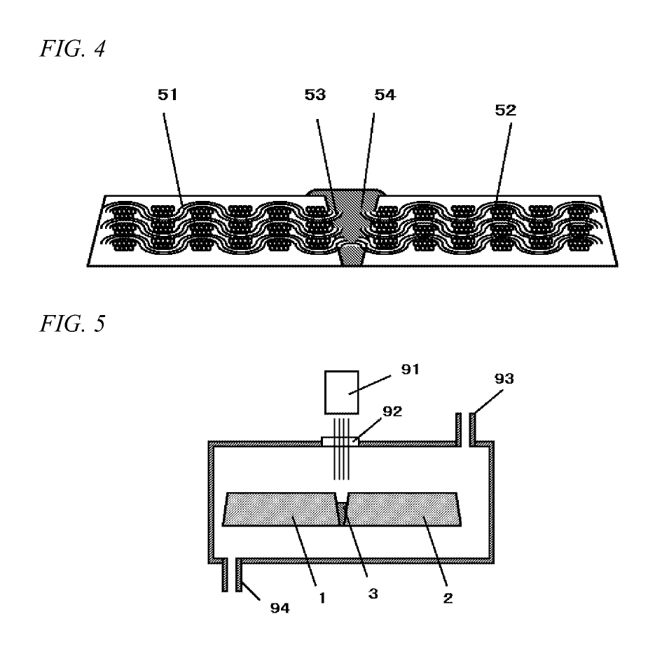

FIG. 3(a) shows a ceramic joined body 100 of Embodiment 2 of the invention, in which cylindrical first ceramic component 1 and second ceramic component 2 having the same shape of the bottom face and the same size are joined with a joining part 3 so that the bottom faces meet each other.

The first ceramic component 1 and the second ceramic component 2 have, for example, an outer diameter of 100 to 500 mm, a thickness of 1 to 20 mm, and a length of 100 to 1000 mm. The joining part 3 is formed as in Embodiment 1. In the present embodiment, since the joining part 3 is configured in a cyclic shape, the ceramic joined body 100 of the present embodiment can be obtained by rotating the first ceramic component 1 and the second ceramic component 2 in the reaction vessel. Moreover, since the ceramic joined body 100 of the embodiment is cyclic, it is symmetric to the center axis and has a characteristic that thermal strain is less likely to take place.

### Embodiment 3

FIG. 3(a) shows a ceramic joined body 100 of Embodiment 3 of the invention, in which square pipe-shaped first ceramic component 1 and second ceramic component 2 having the same shape of the bottom face and the same size are joined with a joining part 3 so that the bottom faces meet each other.

The first ceramic component 1 and the second ceramic component 2 have, for example, a one-side length of 30 to 500 mm, a thickness of 1 to 20 mm, and a length of 100 to 1000 mm. The joining part 3 is formed as in Embodiment 1. In the present embodiment, since the joining part 3 is configured in a rectangular shape, the ceramic joined body 100 of the present embodiment can be obtained by rotating the first ceramic component 1 and the second ceramic component 2 in the reaction vessel. Moreover, since the ceramic joined body 100 of the embodiment has a square pipe-shape, it is symmetric to the center axis and has a characteristic that thermal strain is less likely to take place.

### Embodiment 4

It is a cross-sectional view of a ceramic joined body 100 of Embodiment 4 in which the first ceramic component 1 and the second ceramic component 2 have ceramic fibers 51 and 52, respectively. The whole shape is the same as in Embodiment 1.

The first ceramic component 1 and the second ceramic component 2 have a matrix of SiC and have SiC fibers that are ceramic fibers 51 and 52 inside as woven fabrics. End parts 53 and 54 of the ceramic fibers are exposed on the first face 11 of the first ceramic component 1 and the second face 21 of the second ceramic component 2. This can be obtained by notching both sides of a SiC/SiC composite material and splitting it to cause extraction of the ceramic fibers. Incidentally, surfaces of the ceramic fibers may be coated so that the ceramic fibers may be easily drawn. In the case of the SiC/SiC composite material, for example, coating with carbon can be formed on surfaces of the SiC fibers. The coating with carbon can be obtained by applying a resin and firing it under an inert atmosphere.

In the thus obtained ceramic joined body 100 of the present embodiment, since the first ceramic component and the second ceramic component and the joining part 3 are joined with the end parts of the ceramic fibers, a ceramic joined body having high strength can be obtained.

As above, the ceramic joined body 100 is obtained by joining the first ceramic component 1 and the second ceramic component 2 with the joining part 3 including a CVD ceramic, as described with reference to the embodiments of Embodiments 1 to 4. Therefore, since the ceramic joined body 100 can be integrally obtained, a large ceramic joined body can be easily obtained even in the case where a ceramic component manufacturing apparatus is constrained in size.

### INDUSTRIAL APPLICABILITY

The ceramic joined body of the present invention may be used as heat-resistant components such as wafer boats to be used at thermal treatment of semiconductor wafers, components for a plasma etcher apparatus, and components for a semiconductor manufacturing apparatus, in addition to heat-resistant components of industrial furnaces and the like.

### DESCRIPTION OF REFERENCE NUMERALS AND SIGNS

1 First ceramic component
2 Second ceramic component
3 Joining part
4 Gap
11 First face
12 Third face
21 Second face
22 Fourth face
31 First coating part
32 Second coating part
51, 52 Ceramic fibers
53, 54 End parts of ceramic fibers
91 Laser light source
92 Window
93 Gas inlet port
94 Gas discharge port
100 Ceramic joined body

1. A ceramic joined body comprising:
a first ceramic component having a first face;
a second ceramic component having a second face; and
a joining part including a CVD ceramic that fills a region where the first face and the second face are facing each other.

2. The ceramic joined body according to claim 1,
wherein the CVD ceramic is formed by a photo-CVD method.

3. The ceramic joined body according to claim 1,
wherein the first ceramic component has a third face extending away from the joining part, and
wherein the ceramic joined body further comprises:
a first coating part including a CVD ceramic that coats the third face at a portion near the joining part.

4. The ceramic joined body according to claim 3,
wherein the second ceramic component has a fourth face extending away from the joining part, and
wherein the ceramic joined body further comprises:
a second coating part including a CVD ceramic that coats the fourth face at a portion near the joining part.

5. The ceramic joined body according to claim 3,
wherein the CVD ceramic filled into the joining part is thicker than both of the first coating part and the second coating part.

6. The ceramic joined body according to claim 1,
wherein the joining part is configured to be thinner at inside than at a surface.

7. The ceramic joined body according to claim 1,
wherein the first ceramic component is a composite material having a ceramic fiber inside, and
wherein an end part of the ceramic fiber is protruded from the first face into the joining part.

8. The ceramic joined body according to claim 7,
wherein the second ceramic component is a composite material having a ceramic fiber inside, and
wherein an end part of the ceramic fiber is protruded from the second face into the joining part.

9. The ceramic joined body according to claim 1,
wherein the CVD ceramic includes a MAX phase ceramic defined by the following composition formula:
Mₙ₊₁AXₙ
wherein:
(a) M is any element selected from a group consisting of Sc, Ti, V, Cr, Zr, Nb, Mo, Hf, and Ta;
(b) A is any element selected from a group consisting of Al, Si, P, S, Ga, Ge, As, Cd, In, Sn, Ti, and Pb;
(c) X is C or N; and
(d) n is 0.5 or more and 3 or less (0.5≦n≦3).

10. The ceramic joined body according to claim 9,
wherein the MAX phase ceramic is Ti₃SiC₂.

11. A heat-resistant component provided with the ceramic joined body according to claim 1.

12. The heat-resistant component according to claim 11,
wherein the heat-resistant component is used for a semiconductor manufacturing apparatus.

13. A method for manufacturing a ceramic joined body, the method comprising:
placing a first ceramic component having a first face and a second ceramic component having a second face so as to form a gap where the first face and the second face are facing each other; and
forming a joining part including a CVD ceramic that joins the first ceramic component and the second ceramic component by a photo-CVD method in which a source gas is fed to the gap and light irradiation is performed to the first face or the second face through the gap.

14. The method for manufacturing a ceramic joined body according to claim 13,
wherein the first ceramic component has a third face extending away from the joining part, and
wherein the light irradiation is performed to irradiate into and around the gap to form a first coating part including a CVD ceramic that coats the third face at a portion near the joining part.

15. The method for manufacturing a ceramic joined body according to claim 14,
wherein the second ceramic component has a fourth face extending away from the joining part, and
wherein the light irradiation is performed to irradiate into and around the gap to form a second coating part including a CVD ceramic that coats the fourth face at a portion near the joining part.

16. The method for manufacturing a ceramic joined body according to claim 14,
wherein the CVD ceramic filled into the joining part is formed thicker than both of the first coating part and the second coating part by performing the light irradiation to be focused into the gap.

17. The method for manufacturing a ceramic joined body according to claim 13,
wherein the joining part is formed so as to be thinner at inside than at a surface by placing the first ceramic component and the second ceramic component so that the gap is narrower at the inside than at the surface.

18. The method for manufacturing a ceramic joined body according to claim 13,
wherein the first ceramic component is a composite material having a ceramic fiber, in which an end part of the ceramic fiber protrudes from the first face, and the joining part is formed so that the end part is encapsulated.

19. The method for manufacturing a ceramic joined body according to claim 18,
wherein the second ceramic component is a composite material having a ceramic fiber, in which an end part of the ceramic fiber protrudes from the second face, and the joining part is formed so that the end part is encapsulated.

20. The method for manufacturing a ceramic joined body according to claim 13,
wherein the CVD ceramic includes a MAX phase ceramic defined by the following composition formula:
Mₙ₊₁AXₙ
wherein:
(a) M is any element selected from the group consisting of Sc, Ti, V, Cr, Zr, Nb, Mo, Hf, and Ta;
(b) A is any element selected from the group consisting of Al, Si, P, S, Ga, Ge, As, Cd, In, Sn, Ti, and Pb;
(c) X is C or N; and
(d) n is 0.5 or more and 3 or less (0.5≦n≦3), and
wherein the joining part is formed using:
a halide, a hydride, or a hydrocarbylate containing M;
a halide, a hydride, or a hydrocarbylate containing A; and
an organic substance, an oxide, ammonia, or an amine containing X, as the source gas:

21. The method for manufacturing a ceramic joined body according to claim 20,
wherein the MAX phase ceramic is Ti₃SiC₂, and
wherein the joining part is formed using a titanium halide, a silicon halide, and a carbon halide as the source gas.
